(19) United States
(12) Patent Application Publication
(10) Pub. No.: US 2016/0368175 A1
(43) Pub. Date: Dec. 22, 2016

(54) MOLD RELEASE FILM AND PROCESS FOR PRODUCING SEALED BODY

(71) Applicant: Asahi Glass Company, Limited, Chiyoda-ku (JP)

(72) Inventors: Wataru KASAI, Chiyoda-ku (JP); Masami SUZUKI, Chiyoda-ku (JP)

(73) Assignee: Asahi Glass Company, Limited, Chiyoda-ku (JP)

(21) Appl. No.: 15/256,913

(22) Filed: Sep. 6, 2016

Related U.S. Application Data
(63) Continuation of application No. PCT/JP2015/056738, filed on Mar. 6, 2015.

(30) Foreign Application Priority Data
Mar. 7, 2014 (JP) 2014-045467

(51) Int. Cl. B29C 33/68; B29C 45/02; B29C 43/18; B32B 27/32; H01L 21/56; B32B 27/36; B32B 27/08; B32B 37/12; B32B 37/10; B29C 45/14; B32B 27/34

(52) U.S. Cl. CPC B29C 33/68; B29C 45/14655; B29C 45/02; B29C 43/18; B32B 27/322; B32B 27/34; B32B 27/36; B32B 27/08; B32B 37/12; B32B 37/10; H01L 21/566; B29C 2045/14663; B29K 2627/18

(57) ABSTRACT

To provide a mold release film having excellent releasing properties for a sealed body from a mold and excellent followability to a mold requiring significant deformation, in a method for producing a sealed body wherein a structure comprising a substrate, a semiconductor element and connection terminals, is disposed in a mold requiring significant deformation and sealed with a curable resin to form a resin sealed portion having a thickness of at least 3 mm. The mold release film has a first layer to be in contact with the curable resin at the time of forming the resin sealed portion, and a second layer, wherein the first layer has a thickness of from 5 to 30 μm and is made of at least one member selected from the group consisting of a fluororesin and a polyolefin having a melting point of at least 200° C., and the second layer has a thickness of from 38 to 100 μm, a product of the tensile storage modulus (MPa) at 180° C. and the thickness (μm) being at most 18,000 (MPa·μm), and a product of the tensile stress at break (MPa) at 180° C. and the thickness (μm) being at least 2,000 (MPa·μm).

### TECHNICAL FIELD

The present invention relates to a mold release film to be used in a method for producing a sealed body wherein a structure comprising a substrate, a semiconductor element and connection terminals is disposed in a mold requiring significant deformation and sealed with a curable resin to form a resin sealed portion having a thickness of at least 3 mm, and a process for producing a sealed body by using the mold release film.

### BACKGROUND ART

In a power semiconductor module as one of semiconductor modules or ECU (an engine control unit) for automobiles, the substrate after being mounted is required to have heat resistance and reliability, and therefore, in its production process, a step of sealing the substrate itself with a resin (a sealing resin) is carried out. Such sealing is usually carried out by potting liquid or gelled silicone on the substrate, followed by curing. However, the sealing by potting involves such problems that a case is required to inject the silicone, it takes time for curing, and there is a structural restriction such that the potting surface necessarily becomes flat. Therefore, in recent years, a method for sealing by transfer molding by using a thermosetting resin such as an epoxy resin has been adopted.

The production of a semiconductor module by transfer molding is usually carried out by disposing a substrate having a semiconductor element or a passive component mounted thereon, and other components such as a heatsink, etc., in a mold, and injecting a thermosetting resin, followed by curing. Thereafter, releasing from the mold is required, and therefore, a mold release agent is incorporated in the thermosetting resin in order to secure the mold releasability (e.g. Patent Document 1).

However, incorporation of a mold release agent is likely to impair the adhesion of the sealing resin and the substrate, thus bringing about a problem that the reliability of the semiconductor module tends to be low.

As a mold release method without using a mold release agent, a mold release film made of a resin such as a fluororesin may sometimes be disposed on a surface to be in contact with the curable resin of the mold, in order to prevent adhesion of the curable resin and the mold. The mold release film is usually stretched along the surface of the mold by vacuum suctioning and brought in such a state as closely in contact with the mold. This method is employed in the production of a thin film type package having a thickness of at most about 1 mm, such as a semiconductor package to seal one semiconductor element.

However, if the mold release film commonly employed in such an application is used for the production of a semiconductor module which is thick and complicated in shape as compared with the semiconductor package, there is a problem such that the mold release film deforms to a large extent, and the mold release film is likely to rupture before it follows up the mold. For example, in the case of an angular cavity, at the angular portion, the mold release film tends to be stretched to a large extent, so that pinholes are likely to be formed. Rupturing of the mold release film tends to be more likely as the mold becomes large and complicated. Once the mold release film is ruptured, the thermosetting resin leaks out from the ruptured portion and adheres to the mold. The curable resin adhered to the mold will bring about the appearance failure at the time of sealing another structure, and therefore, cleaning of the mold is required, thus leading to deterioration in the productivity of the semiconductor module.

Further, in Patent Document 2, in order to expose a heatsink as a component of a semiconductor module, a flexible mold release sheet is disposed between the heat release surface of a lead frame and the mold, and transfer molding is carried out in such a state that the above heat release surface is embedded in the above flexible mold release sheet. However, the role of the flexible mold release sheet is just to expose the heatsink and does not contribute to releasing of the semiconductor module from the mold.

### PRIOR ART DOCUMENTS

### Patent Documents

Patent Document 1: JP-A-2010-245188

Patent Document 2: JP-A-2012-28595

### DISCLOSURE OF INVENTION

### Technical Problem

It is an object of the present invention to provide a mold release film having excellent releasing properties for a sealed body from a mold and excellent followability to a mold requiring significant deformation, in a method for producing a sealed body wherein a structure comprising a substrate, a semiconductor element and connection terminals, is disposed in a mold requiring significant deformation and sealed with a curable resin to form a resin sealed portion having a thickness of at least 3 mm, and a process for producing a sealed body by using such a mold release film.

### Solution to Problem

The present invention provides a mold release film and a process for producing a sealed body, having the following constructions [1] to [10].

[1] In a method for producing a sealed body wherein a structure comprising a substrate, a semiconductor element and connection terminals is disposed in a mold comprising an upper mold and a lower mold, of which at least one has a depth of at least 3 mm, and sealed with a curable resin to form a resin sealed portion having a thickness of at least 3 mm, a mold release film to be disposed on a surface, to be in contact with the curable resin, of said at least one of the upper mold and the lower mold having a depth of at least 3 mm, characterized in that

it has a first layer to be in contact with the curable resin at the time of forming the resin sealed portion, and a second layer,

the first layer has a thickness of from 5 to 30 μm and is made of at least one member selected from the group consisting of a fluororesin and a polyolefin having a melting point of at least 200° C., and

the second layer has a thickness of from 38 to 100 μm, a product of the tensile storage modulus (MPa) at 180° C. and the thickness (μm) being at most 18,000 (MPa·μm), and a product of the tensile stress at break (MPa) at 180° C. and the thickness (μm) being at least 2,000 (MPa·μm).

[2] The mold release film according to [1], wherein the first layer is made of a fluoroolefin type polymer or a polymethylpentene.
[3] The mold release film according to [1], wherein the first layer is made of a copolymer having units based on a tetrafluoroolefin and units based on ethylene.
[4] The mold release film according to any one of [1] to [3], wherein the second layer is made of a resin for the second layer, and the glass transition temperature of the resin for the second layer is from 40 to 105° C.
[5] The mold release film according to any one of [1] to [4], wherein the second layer is made of at least one member selected from the group consisting of non-stretched polyamide, polybutylene terephthalate and highly formable polyethylene terephthalate.
[6] The mold release film according to any one of [1] to [5], wherein the arithmetic mean roughness (Ra) of the surface on the mold surface side of the second layer is from 1.5 to 2.1 μm.
[7] The mold release film according to any one of [1] to [6], wherein (the tensile storage modulus (MPa) at 180° C.×the thickness (μm))/(the tensile stress at break (MPa) at 180° C.×the thickness (μm)) of the second layer is less than 3.8.
[8] A process for producing a sealed body having a resin sealed portion with a thickness of at least 3 mm, formed from a substrate, a semiconductor element, connection terminals and a curable resin, by means of a mold comprising an upper mold and a lower mold, of which at least one has a depth of at least 3 mm, characterized by comprising:

a step of disposing the mold release film as defined in any one of [1] to [4] on a surface, to be in contact with the curable resin, of said at least one of the upper mold and the lower mold having a depth of at least 3 mm,

a step of disposing a structure comprising a substrate, a semiconductor element and connection terminals in the mold and filling a pace in the mold with the curable resin, followed by curing to form a resin sealed portion having a thickness of at least 3 mm, and

a step of releasing the resin sealed portion together with the structure from the mold.

[9] The process for producing a sealed body according to [8], which comprises the following steps (α1) to (α5):

(α1) a step of disposing the mold release film on the lower mold of the mold comprising the lower mold having a concave portion with a depth of at least 3 mm and the upper mold not having a concave portion with a depth of at least 3 mm, so that the mold release film covers the concave portion of the lower mold,

(α2) a step of vacuum-suctioning the mold release film to the side of the cavity surface of the lower mold,

(α3) a step of filling the curable resin in the concave portion of the lower mold,

(α4) a step of disposing a structure comprising a substrate, a laminate structure and through-silicon vias between the upper mold and the lower mold, closing the upper mold and the lower mold, and filling the curable resin in a cavity formed between the upper mold and the lower mold, followed by curing to form a resin sealed portion 19 thereby to obtain a sealed body, and

(α5) a step of taking out the sealed body from the mold.

[10] The process for producing a sealed body according to [8], which comprises the following steps (β1) to (β5):

(β1) a step of disposing the mold release film on the upper mold of the mold comprising the upper mold having a concave portion with a depth of at least 3 mm and the lower mold not having a concave portion with a depth of at least 3 mm, so that the mold release film covers the concave portion of the upper mold,

(β2) a step of vacuum-suctioning the mold release film to the side of the cavity surface of the upper mold,

(β3) a step of disposing a structure comprising a substrate, a laminate structure and through-silicon vias at a predetermined position in the lower mold, and closing the upper mold and the lower mold,

(β4) a step of filling the curable resin in a cavity formed between the upper mold and the lower mold, followed by curing to form a resin sealed portion thereby to obtain a sealed body, and

(β5) a step of taking out the sealed body from the mold.

### Advantageous Effects of Invention

The mold release film of the present invention has excellent releasing properties for the sealed body from the mold and excellent followability to the mold requiring significant deformation.

Further, since the mold release film of the present invention has excellent releasing properties for the sealed body from the mold, according to the process for producing a sealed body of the present invention, it is possible to let the mold release film to follow up the mold requiring significant deformation with excellent followability, and to let the sealed body be released from the mold with excellent releasability.

### BRIEF DESCRIPTION OF DRAWINGS

FIG. 1 is a schematic cross-sectional view showing a first embodiment of the mold release film of the present invention.

FIG. 2 is a cross-sectional view showing an example of the sealed body to be produced by the process for producing a sealed body of the present invention.

FIG. 3 is a cross-sectional view illustrating schematically step (α3) in a first embodiment of the process for producing a sealed body of the present invention.

FIG. 4 is a cross-sectional view illustrating schematically step (α4) in the first embodiment of the process for producing a sealed body of the present invention.

FIG. 5 is a cross-sectional view illustrating schematically step (α4) in the first embodiment of the process for producing a sealed body of the present invention.

FIG. 6 is a cross-sectional view showing an example of the mold used in a second embodiment of the process for producing a sealed body of the present invention.

FIG. 7 is a cross-sectional view illustrating schematically step (β1) in the second embodiment of the process for producing a sealed body of the present invention.

FIG. 8 is a cross-sectional view illustrating schematically step (β2) in the second embodiment of the process for producing a sealed body of the present invention.

FIG. 9 is a cross-sectional view illustrating schematically step (β3) in the second embodiment of the process for producing a sealed body of the present invention.

FIG. 10 is a cross-sectional view illustrating schematically step (β4) in the second embodiment of the process for producing a sealed body of the present invention.

FIG. 11 is a cross-sectional view illustrating schematically step (β5) in the second embodiment of the process for producing a sealed body of the present invention.

FIG. 12 is a schematic cross-sectional view illustrating another example of the sealed body obtainable by the process for producing a sealed body of the present invention.

FIG. 13 is a view illustrating the test method for 180° C. followability test in Examples.

### DESCRIPTION OF EMBODIMENTS

In this specification, the following terms are used in the following meanings, respectively.

In a resin, “units” means structural units (monomer units) that constitute the resin.

A “fluororesin” means a resin containing fluorine atoms in its structure.

The depth of the upper mold or the lower mold means the depth of the concave portion of the upper mold or the lower mold, when the upper mold and the lower mold are closed to form a cavity. The depth of the concave portion means the maximum depth in a vertical direction to the interface between the upper mold and the lower mold. As between the upper mold and the lower mold, one having a concave portion with a depth of at least 3 mm may be either one of them, or both of them. In a case where either one of them has a concave portion with a depth of at least 3 mm, the other one may have a concave portion with a depth of at least 3 mm, or a concave portion with a depth of more than 0 and less than 3 mm, or may not have a concave portion.

The thickness of the resin sealed portion means the maximum thickness of the resin sealed portion in a vertical direction to the substrate surface.

The thickness of the mold release film, the thickness of a layer (such as a second layer or a first layer) constituting a mold release film of a multi-layer structure, the tensile storage modulus at 180° C. and the tensile stress at break at 180° C. are, respectively, measured by the methods as described in Examples.

An arithmetic mean roughness (Ra) is an arithmetic mean roughness to be measured in accordance with JIS B0601: 2013 (ISO4287: 1997, Amd.1: 2009). The standard length Ir (cut-off value λc) for roughness curve was set to be 0.8 mm.

### [Mold Release Film]

The mold release film of the present invention is, in a method for producing a sealed body wherein a structure comprising a substrate, a semiconductor element and connection terminals is disposed in a mold comprising an upper mold and a lower mold, of which at least one has a depth of at least 3 mm, and sealed with a curable resin to form a resin sealed portion having a thickness of at least 3 mm, a mold release film to be disposed on a surface, to be in contact with the curable resin, of said at least one of the upper mold and the lower mold having a depth of at least 3 mm (hereinafter referred to also as the mold having a depth of at least 3 mm), characterized in that

it has a first layer to be in contact with the curable resin at the time of forming the resin sealed portion, and a second layer,

the first layer has a thickness of from 5 to 30 μm and is made of at least one member selected from the group consisting of a fluororesin and a polyolefin having a melting point of at least 200° C., and

the second layer has a thickness of from 38 to 100 μm, a product of the tensile storage modulus (MPa) at 180° C. and the thickness (μm) being at most 18,000 (MPa·μm), and a product of the tensile stress at break (MPa) at 180° C. and the thickness (μm) being at least 2,000 (MPa·μm).

The mold release film of the present invention is to be disposed on the surface to be in contact with the curable resin, of the mold having a thickness of at least 3 mm, so that its first layer side surface faces the cavity. Since the mold release film has the first layer, the releasability of the sealed body from the mold will be excellent after curing of the curable resin.

Further, the thickness of the first layer is at most the prescribed level, and the mold release film has the second layer, whereby it is less likely to be ruptured even if stretched to a large extent, and it is excellent in followability to the mold having a depth of at least 3 mm.

### (Mold Release Film in First Embodiment)

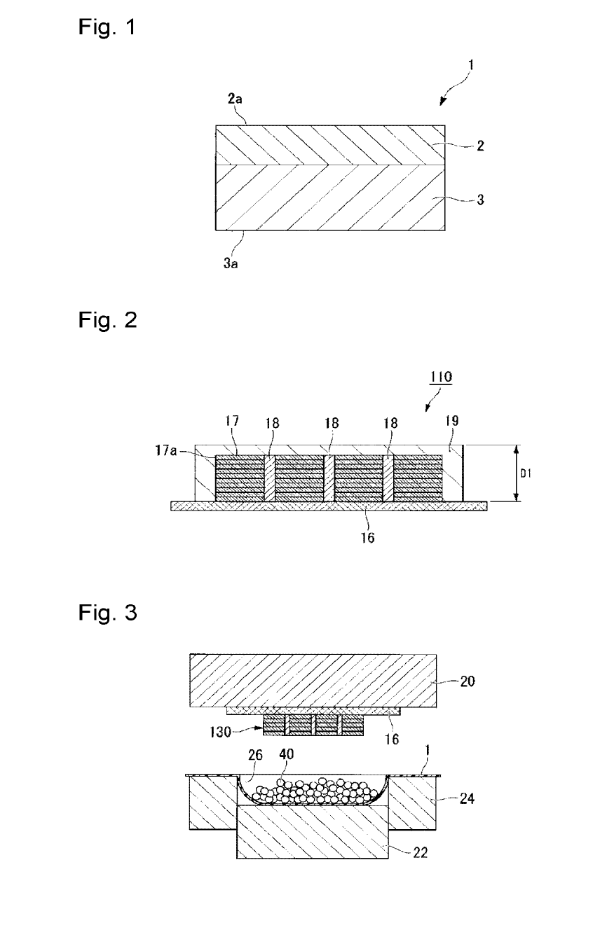

FIG. 1 is a schematic cross-sectional view showing a first embodiment of the mold release film of the present invention. The mold release film 1 in the first embodiment is one having a first layer 2 and a second layer 3 laminated in this order. The mold release film 1 is such that the first layer 2 is to be in contact with the curable resin, and the second layer 3 is to be in contact with the mold.

### <First Layer>

The thickness of the first layer 2 is from 5 to 30 μm, preferably from 12 to 30 μm. When the thickness of the first layer 2 is at least the lower limit value in the above range, the releasability of the sealed body from the mold will be excellent. When it is at most the upper limit value, the mold release film 1 will follow up the mold having a depth of at least 3 mm without being ruptured.

The first layer 2 is made of at least one member (hereinafter referred to also as a resin for the first layer) selected from the group consisting of a fluororesin and a polyolefin having a melting point of at least 200° C. As the resin for the first layer, one type may be used alone, or two or more types may be used in combination.

When the first layer 2 to be directly in contact with the curable resin is made of the resin for the first layer, the releasability of the sealed body from the mold will be excellent. Further, as it is made of the resin for the first layer, the first layer 2 has heat resistance durable against the temperature of the mold during molding (typically from 150 to 180° C.), and there will be little transfer to the sealed body surface, of a resin low molecular substance attributable to heat decomposition, such being desirable.

From the viewpoint of mold releasability and heat resistance, the fluororesin is preferably a fluoroolefin type polymer. The fluoroolefin type polymer is a polymer having units based on a fluoroolefin. The fluoroolefin may, for example, be tetrafluoroethylene, vinyl fluoride, vinylidene fluoride, trifluoroethylene, hexafluoropropylene, chlorotrifluoroethylene, etc. As the fluoroolefin, one type may be used alone, or two or more types may be used in combination.

The fluoroolefin type polymer may, for example, be an ethylene/tetrafluoroethylene copolymer (hereinafter referred to also as ETFE), polytetrafluoroethylene, a perfluoro(alkyl vinyl ether)/tetrafluoroethylene copolymer, etc. As the fluoroolefin type polymer, one type may be used alone, or two or more types may be used in combination.

Among such fluoroolefin type polymers, ETFE is particularly preferred, since the elongation at a high temperature is large.

ETFE is a copolymer comprising units based on tetrafluoroethylene (hereinafter referred to also as TFE) and units based on ethylene (hereinafter referred to also as E).

ETFE is preferably one having units based on TFE, units based on E and units based on a third monomer other than TFE and E. It is easy to adjust the crystallinity of ETFE i.e. the tensile storage modulus of the first layer 2, by the type and content of units based on the third monomer. Further, by having units based on the third monomer (especially a monomer having fluorine atoms), the tensile strength and elongation at a high temperature (especially at about 180° C.) will be improved.

As the third monomer, a monomer having fluorine atoms or a monomer having no fluorine atom may be mentioned.

As the monomer having fluorine atoms, the following monomers (a1)) to (a5) may be mentioned.

Monomer (a1): a fluoroolefin having at most 3 carbon atoms.

Monomer (a2): a perfluoroalkyl ethylene represented by X(CF₂)ₙCY═CH₂ (wherein X and Y are each independently a hydrogen atom or a fluorine atom, and n is an integer of from 2 to 8).

Monomer (a3): a fluorovinylether.

Monomer (a4): a functional group-containing fluorovinylether.

Monomer (a5): a fluorinated monomer having an aliphatic ring structure.

The monomer (a1)) may, for example, be a fluoroethylene (such as trifluoroethylene, vinylidene fluoride, vinyl fluoride or chlorotrifluoroethylene), or a fluoropropylene (such as hexafluoropropylene (hereinafter referred to also as HFP), or 2-hydropentafluoropropylene).

The monomer (a2) is preferably a monomer wherein n is from 2 to 6, particularly preferably a monomer wherein n is from 2 to 4. Also, a monomer wherein X is a fluorine atom, and Y is a hydrogen atom, i.e. a (perfluoroalkyl)ethylene, is particularly preferred.

As specific examples of the monomer (a2), the following compounds may be mentioned.

CF₃CF₂CH═CH₂,

CF₃CF₂CF₂CF₂CH═CH₂ ((perfluorobutyl)ethylene; hereinafter referred to also as PFBE),

CF₃CF₂CF₂CF₂CF═CH₂,

CF₂HCF₂CF₂CF═CH₂,

CF₂HCF₂CF₂CF₂CF═CH₂, etc.

As specific examples of the monomer (a3), the following compounds may be mentioned. Here, among the following, a monomer which is a diene, is a cyclo-polymerizable monomer.

CF₂═CFOCF₃,

CF₂═CFOCF₂CF₃,

CF₂═CF(CF₂)₂CF₃ (perfluoro(propyl vinyl ether); hereinafter referred to also as PPVE),

CF₂═CFOCF₂CF(CF₃)O(CF₂)₂CF₃,

CF₂═CFO(CF₂)₃O(CF₂)₂CF₃,

CF₂═CFO(CF₂CF(CF₃)O)₂(CF₂)₂CF₃,

CF₂═CFOCF₂CF(CF₃)O(CF₂)₂CF₃,

CF₂═CFOCF₂CF═CF₂,

CF₂═CFO(CF₂)₂CF═CF₂, etc.

As specific examples of the monomer (a4), the following compounds may be mentioned.

CF₂═CFO(CF₂)₃CO₂CH₃,

CF₂═CFOCF₂CF(CF₃)O(CF₂)₃CO₂CH₃,

CF₂═CFOCF₂CF(CF₃)O(CF₂)₂SO₂F, etc.

As specific examples of the monomer (a5), perfluoro(2,2-dimethyl-1,3-dioxole), 2,2,4-trifluoro-5-trifluoromethoxy-1,3-dioxole, perfluoro(2-methylene-4-methyl-1,3-dioxolane), etc. may be mentioned.

As the monomer having no fluorine atom, the following monomers (b1) to (b4) may be mentioned.

Monomer (b1): an olefin.

Monomer (b2): a vinyl ester.

Monomer (b3): a vinyl ether.

Monomer (b4): an unsaturated acid anhydride.

As specific examples of the monomer (b1), propylene, isobutene, etc. may be mentioned.

As specific examples of the monomer (b2), vinyl acetate, etc. may be mentioned.

As specific examples of the monomer (b3), ethyl vinyl ether, butyl vinyl ether, cyclohexyl vinyl ether, hydroxybutyl vinyl ether, etc. may be mentioned.

As specific examples of the monomer (b4), maleic anhydride, itaconic anhydride, citraconic anhydride, himic anhydride (5-norbornene-2,3-dicarboxylic acid anhydride), etc. may be mentioned.

As the third monomer, one type may be used alone, or two or more types may be used in combination.

The third monomer is preferably the monomer (a2), HFP, PPVE or vinyl acetate, more preferably HFP, PPVE, CF₃CF₂CH═CH₂ or PFBE, particularly preferably PFBE, in that adjustment of the crystallinity, i.e. the tensile storage modulus, will be thereby easy, and by having units based on a third monomer (especially a monomer having fluorine atoms), the tensile strength and elongation at a high temperature (particularly at about 180° C.) will be excellent.

That is, as ETFE, particularly preferred is a copolymer having units based on TFE, units based on E and units based on PFBE.

In ETFE, the molar ratio (TFE/E) of units based on TFE to units based on E is preferably from 80/20 to 40/60, more preferably from 70/30 to 45/55, particularly preferably from 65/35 to 50/50. When TFE/E is within the above range, the heat resistance and mechanical properties of ETFE will be excellent.

The proportion of units based on the third monomer in ETFE is preferably from 0.01 to 20 mol %, more preferably from 0.10 to 15 mol %, particularly preferably from 0.20 to 10 mol %, based on the total (100 mol %) of all units constituting ETFE. When the proportion of units based on the third monomer is within the above range, the heat resistance and mechanical properties of ETFE will be excellent.

In a case where the units based on the third monomer contain units based on PFBE, the proportion of units based on PFBE is preferably from 0.5 to 4.0 mol %, more preferably from 0.7 to 3.6 mol %, particularly preferably from 1.0 to 3.6 mol %, based on the total (100 mol %) of all units constituting ETFE. When the proportion of units based on PFBE is within the above range, the first layer 2 will be excellent in heat resistance. Further, the tensile strength and elongation at a high temperature (especially at about 180° C.) will be improved.

The melt flow rate (MFR) of ETFE is preferably from 2 to 40 g/10 min, more preferably from 5 to 30 g/10 min, particularly preferably from 10 to 20 g/10 min. When

MFR is within the above range, the moldability of ETFE will be improved, and the mechanical properties of the first layer 2 will be excellent.

MFR of ETFE is a value as measured under a load of 49 N at 297° C. in accordance with ASTM D3159.

The melting point of the polyolefin having a melting point of at least 200° C. is preferably from 200° C. to 300° C.

As the polyolefin having a melting point of at least 200° C., polymethylpentene is preferred. As the polyolefin, one type may be used alone, or two or more types may be used in combination.

As the resin for the first layer, among the above mentioned ones, a fluoroolefin type polymer is preferred, and ETFE is particularly preferred. As ETFE, one type may be used alone, or two or more types may be used in combination.

The first layer 2 may be one made solely of the resin for the first layer, or one having an additive such as an inorganic additive or an organic additive incorporated. As the inorganic additive, inorganic fillers such as carbon black, silica, glass fibers, carbon nanofibers, titanium oxide, etc., may be mentioned. As the organic additive, silicone oil, metal soap, etc. may be mentioned.

### <Second Layer>

The thickness of the second layer 3 is from 38 to 100 μm, preferably from 50 to 100 μm. When the thickness of the second layer 3 is at least the lower limit value in the above range, the mold release film 1 is less likely to be ruptured at the time of letting the mold release film follow up a mold having a depth of at least 3 mm, even if the shape of the mold is complicated. When it is at most the upper limit value in the above range, the mold release film 1 can easily be deformed, and even in a case where the shape of the mold is complicated, the mold release film 1 will be closely in contact with the mold, whereby a high quality resin sealed portion can constantly be formed.

The product of the tensile storage modulus (MPa) at 180° C. and the thickness (μm) of the second layer is at most 18,000 (MPa·μm), preferably at most 14,000 (MPa·μm). When the thickness of the second layer 3 is within the above range, and the product of this thickness (μm) and the tensile storage modulus (MPa) at 180° C. is at most the above upper limit value, the mold followability will be excellent even in the case of a deep mold with a depth of at least 3 mm. The lower limit value for the above product is preferably 3,000, particularly preferably 4,000. When the above product is at least the lower limit value, the handling efficiency in roll-to-roll will be excellent.

The tensile storage modulus at 180° C. of the second layer 3 may be adjusted by the crystallinity of the resin constituting the second layer (hereinafter referred to also as the resin for the second layer). Specifically, as the crystallinity of the resin is lower, the tensile storage modulus of the layer made of the resin becomes lower. The crystallinity of the resin can be adjusted by a known method. For example, in the case of an ethylene/tetrafluoroethylene copolymer, the crystallinity can be adjusted by the type or proportion of units based on a monomer other than tetrafluoroethylene and ethylene. The tensile storage modulus at 180° C. of the second layer 3 is preferably from 50 to 400 MPa, particularly preferably from 50 to 300 MPa.

(The tensile storage modulus (MPa) at 180° C.×the thickness (μm))/(the tensile stress at break (MPa) at 180° C.×the thickness (μm)) of the second layer 3 is preferably less than 3.8, particularly preferably less than 3.5. If it is 3.8 or more, the mold followability at the time of vacuum suctioning to the mold tends to be inadequate, and in the case of a deep mold, rupturing is likely to occur. The lower limit is not particularly set.

The product of the tensile stress at break (MPa) at 180° C. and the thickness (μm) of the second layer is at least 2,000 (MPa·μm), preferably at least 3,000 (MPa·μm). When the product of the tensile stress at break (MPa) at 180° C. and the thickness (μm) is at least the above lower limit value, pinholes are less likely to be formed in the mold release film. The upper limit value for the above product is preferably 7,000, particularly preferably 6,000. When the above product is at most the above upper limit value, the mold followability will be excellent.

The tensile stress at break (MPa) at 180° C. of the second layer 3 can be adjusted by the molecular weight, i.e. MFR, of the resin for the second layer. The tensile stress at break (MPa) at 180° C. of the second layer 3 is preferably from 20 to 100 MPa, particularly preferably from 30 to 90 MPa.

The resin for the second layer may be any one so long as the above product of the tensile storage modulus and the thickness, and the tensile stress at break, are within the above ranges, and it may be suitably selected for use among known resins such as thermoplastic resins, rubbers, etc.

The second layer 3 preferably has releasability at such a level that the mold release film 1 can smoothly be peeled from the mold at the time of producing the sealed body. Further, it preferably has heat resistance durable against the temperature of the mold during molding (typically from 150 to 180° C.).

The glass transition temperature (Tg) of the resin for the second layer is preferably from 40 to 105° C., particularly preferably from 40 to 80° C. When it is at least the lower limit value in the above range, the mold release film will be properly flexible, and handling efficiency in roll-to-roll will be good. When it is at most the upper limit value in the above range, the elastic modulus of the film becomes to be sufficiently low at the time of vacuum suctioning the mold release film to the mold, whereby the followability will be excellent.

From these viewpoints, the resin for the second layer is preferably at least one member selected from the group consisting of non-stretched polyamide, polybutylene terephthalate (hereinafter referred to also as PBT) and highly formable polyethylene terephthalate (hereinafter referred to also as PET).

As the polyamide, nylon 6 or nylon MXD6 is preferred from the viewpoint of heat resistance, strength and gas barrier properties.

PBT may further be copolymerized with a polyalkylene glycol. In such a case, polyalkylene glycol units are preferably at most 10 mol % in all units. When the polyalkylene glycol units are contained within such a range, the elastic modulus can be properly lowered. As specific examples of the polyalkylene glycol, polyethylene glycol, polypropylene glycol, polytrimethylene ether glycol, polytetramethylene ether glycol, polyhexamethylene ether glycol, etc. may be mentioned.

The mass average molecular weight (Mw) of PBT is preferably from 50,000 to 100,000, particularly preferably from 60,000 to 90,000. When it is at least the lower limit value in the above range, the tensile stress at break will be high, and rupturing tends to be less likely. When it is at most the upper limit value in the above range, the melt viscosity tends to be low, and it becomes easy to form a thin film having a thickness of at most 100 μm. Here, Mw was calculated by using the following formula (1) by measuring the intrinsic viscosity (n) at 30° C. by means of an Oswald viscometer by dissolving 1 g of the above PBT at room temperature in 100 mL of a solution of phenol and tetrachloroethane in a mass ratio of 1:1.

Mw=4.3×10⁴×[η]^{0.76} (1)

The highly formable PET is one having moldability improved by copolymerizing another monomer in addition to ethylene glycol and terephthalic acid (or dimethyl phthalate). Specifically, it is PET, of which the glass transition temperature Tg as measured by the following method, is at most 105° C.

Tg is a temperature at which tan δ (E″/E′) being a ratio of the loss elastic modulus E″ to the storage elastic modulus E′ as measured in accordance with ISO6721-4: 1994 (JIS K7244-4: 1999) takes the maximum value. Tg is measured by raising the temperature at 2° C./min. from 20° C. to 180° C. at a frequency of 10 Hz, with a static force of 0.98 N and with a dynamic displacement of 0.035%. As the resin for the second layer, one type may be used alone, or two or more types may be used in combination.

The second layer 3 may be one made solely of the resin for the second layer, or one having an additive such as an inorganic additive or an organic additive incorporated. As the inorganic additive and the organic additive, the same ones as described above may be mentioned.

In the mold release film 1, the first layer 2 and the second layer 3 may be directly laminated or may be laminated via an adhesive layer not shown in the drawings.

### <Surface Shape of Mold Release Film>

Of the mold release film 1, the surface to be in contact with the curable resin at the time of forming the resin sealed portion, i.e. the surface 2a on the first layer 2 side, may be smooth or may have irregularities formed. Further, of the mold release film 1, the surface to be in contact with the upper mold of the mold at the time of forming the resin sealed portion, i.e. the surface 3a on the second layer 3 side, may be smooth or may have irregularities formed. When irregularities are formed on the surface 2a, as compared with the case of a smooth surface, the releasability of the sealed body from the mold will be improved. When irregularities are formed on the surface 3a, as compared with the case of a smooth surface, the releasability of the mold release film from the mold will be improved.

The arithmetic average roughness (Ra) of the surface in the case of a smooth surface is preferably from 0.01 to 0.2 μm, particularly preferably from 0.05 to 0.1 μm. Ra of the surface in the case where irregularities are formed, is preferably from 1.5 to 2.1 μm, particularly preferably from 1.6 to 1.9 μm.

The surface shape in the case where irregularities are formed, may be a shape in which a pluralities of convexes and/or concaves are randomly distributed, or may be a shape in which a plurality of convexes and/or concaves are regularly arranged. Further, the shapes and sizes of the plurality of convexes and/or concaves may be the same or different.

The convexes may be elongated ridges extending on the surface of the mold release film, or protrusions or the like scattered on the surface of the mold release film. The concaves may be elongated grooves extending on the surface of the mold release film, or holes or the like scattered on the surface of the mold release film.

The shape of ridges or grooves may be a straight line, curved line or bent line shape. On the surface of the mold release film, a plurality of ridges or grooves may be present in parallel or in stripes. Of ridges or grooves, the cross-sectional shape in a direction perpendicular to the longitudinal direction may be polygonal such as triangular (V-shape), semi-circular or the like.

The shape of the protrusions or holes may be polygonal, such as triangular pyramid, square pyramid or hexagonal pyramid, conical, hemispherical, polyhedral, other various irregular shapes or the like.

In the mold release film 1, both the surface 2a and the surface 3a may be smooth, both the surface 2a and the surface 3a may have irregularities formed thereon, or one of the surface 2a and the surface 3a is smooth, and the other has irregularities formed thereon. In a case where both the surface 2a and the surface 3a have irregularities formed thereon, Ra and/or the surface shapes of the respective surfaces may be the same or different.

### <The Thickness of Mold Release Film>

The thickness of the mold release film 1 is preferably from 43 to 130 μm, particularly preferably from 50 to 130 μm. When the thickness is at least the lower limit value in the above range, handling of the mold release film 1 will be easy, and rupture or wrinkles are less likely to occur when the mold release film 1 is permitted to follow the mold. When the thickness is at most the upper limit value in the above range, the mold release film 1 can be easily deformed, and the mold release film 1 will be in close contact with the mold even if the shape of the mold is complicated, whereby the shape of the mold will be well transferred to a product.

### <Methods for Producing Mold Release Film 1>

The method for producing the mold release film 1 is not particularly limited, and a known method for producing a multi-layered film may be employed. As specific examples, the following methods (1) and (2) may be mentioned, and they may suitably be selected for use in consideration of e.g. the materials, thicknesses, etc. of the respective layers.

(1) A method of laminating a resin film made of the resin for the first layer and a resin film made of the resin for the second layer.

(2) A method of co-extrusion molding the resin for the first layer and the resin for the second layer.

As the method for producing the mold release film 1, the method (1) is preferred from the viewpoint of excellent economic efficiency.

In the method (1), as the method for laminating the respective resin films, known various lamination methods may be employed, and for example, an extrusion lamination method, a dry lamination method, a thermal lamination method, etc. may be mentioned.

In the dry lamination method, the respective resin films are laminated by using an adhesive. As the adhesive, one known as an adhesive for dry lamination may be used. For example, it is possible to use a polyvinyl acetate type adhesive; a polyacrylic acid ester type adhesive made of a homopolymer or copolymer of an acrylic acid ester (such as ethyl acrylate, butyl acrylate, 2-ethylhexyl acrylate, etc.) or a copolymer of an acrylic acid ester with another monomer (such as methyl methacrylate, acrylonitrile, styrene, etc.); a cyanoacrylate type adhesive; an ethylene type adhesive made of e.g. a copolymer of ethylene with another monomer (such as vinyl acetate, ethyl acrylate, acrylic acid, methacrylic acid, etc.); a cellulose type adhesive; a polyester type adhesive; a polyamide type adhesive; a polyimide type adhesive; an amino resin type adhesive made of a urea resin or a melamine resin; a phenol resin type adhesive; an epoxy type adhesive; a polyurethane type adhesive obtained by cross-linking a polyol (such as polyether polyol or polyester polyol) with an isocyanate and/or isocyanurate; a reactive (meth)acrylic adhesive; a rubber type adhesive made of e.g. chloroprene rubber, nitrile rubber, styrene-butadiene rubber, etc.; a silicone type adhesive; an inorganic adhesive made of an alkali metal silicate, low melting point glass, etc.; or other adhesives.

As the resin films to be laminated by the method (1), commercial products may be used, or ones produced by known production methods may be used. The resin films may be ones subjected to surface treatment such as corona treatment, plasma treatment, primer treatment, etc.

The production methods for the resin films are not particularly limited, and known production methods may be employed.

A method for producing a thermoplastic resin film having smooth surfaces on both sides, may, for example, be a melt molding method by means of an extruder equipped with a T-die having a predetermined lip width.

A method for producing a thermoplastic resin film having irregularities formed on one surface or on both surfaces, may, for example, be a method of transferring irregularities of a base die to the surface of a thermoplastic resin film by thermal processing, and from the viewpoint of productivity, the following methods (i), (ii), etc. are preferred. In the methods (i) and (ii), a roll-shaped base die is used, whereby continuous processing becomes possible, and the productivity of a thermoplastic resin film having irregularities formed, will be remarkably improved.

(i) A method wherein a thermoplastic resin film is passed between a base die roll and an impression cylinder roll, so that irregularities formed on the surface of the base die roll are continuously transferred to a surface of the thermoplastic resin film.

(ii) A method wherein a thermoplastic resin extruded from an extruder die is passed between a base die roll and an impression cylinder roll, so that at the same time as molding the thermoplastic resin into a film shape, irregularities formed on the surface of the base die roll are continuously transferred to a surface of the film-shaped thermoplastic resin.

In the methods (i) and (ii), if as the impression cylinder roll, one having irregularities formed on its surface is used, it is possible to obtain a thermoplastic resin film having irregularities formed on both surfaces.

In the foregoing, the mold release film of the present invention has been described with reference to the first embodiment, but the present invention is not limited to the above first embodiment. The respective constructions, their combinations, etc. in the above embodiment are exemplary, and additions, omissions, substitutions and other changes are possible within a range not departing from the concept of the present invention.

For example, the mold release film 1 of the first embodiment may further have another layer other than an adhesive layer which may be provided as the case requires, between the first layer 2 and the second layer 3. As such another layer, a gas barrier layer or an antistatic layer may, for example, be mentioned. The gas barrier layer may, for example, be a metal layer, a metal vapor deposition layer, a metal oxide vapor deposition layer, etc. The antistatic layer may, for example, be a layer formed of an electrically conductive polymer, a layer formed of a thermosetting resin having an electrically conductive polymer, an electrically conductive metal oxide, a metal ion salt, etc.

The mold release film 1 of the first embodiment may further have a third layer to be in contact with the mold at the time of forming the resin sealed portion, on the opposite side to the first layer 2 side, of the second layer 3. In such a case, it may further have an adhesive layer or another layer between the second layer 3 and the third layer, as the case requires.

From the viewpoint of the effects of the present invention, the mold release film of the present invention is preferably one wherein the first layer to be in contact with the curable resin at the time of forming the resin sealed portion, and the second layer, are laminated directly or via an adhesive layer.

### Advantageous Effects

The mold to be used for forming the resin sealed portion in the method for producing a sealed body wherein a structure comprising a substrate, a semiconductor element and connection terminals is disposed in a mold comprising an upper mold and a lower mold, of which at least one has a depth of at least 3 mm, and sealed with a curable resin to form a resin sealed portion having a thickness of at least 3 mm, is deep as compared with a mold to be used for the production of e.g. a semiconductor package for sealing one semiconductor element. Further, for example, in a case where a plurality of components different in height are mounted on a substrate, the surface to be in contact with the curable resin may have a complicated shape. Therefore, a measure to well release the sealed body becomes important, and, for example, a measure to employ a mold having a special construction has been taken.

Further, in the case of carrying out sealing while exposing a component such as a heatsink, if the sealing is conducted in such a state that the component to be exposed and the mold are in contact directly with each other, so-called resin burrs are likely to be formed. Therefore, heretofore, a measure of adding a step of removing the resin burrs has been taken.

The mold release film of the present invention is provided with excellent releasability for the sealed body from the mold and excellent followability to a mold requiring significant deformation.

Since the mold release film of the present invention has excellent releasability for the sealed body from the mold, it is possible to realize good release of the sealed body from the mold even without adding a release agent to the curable resin, or without using a mold having a special construction, by disposing the mold release film of the present invention on the surface of the mold to be in contact with the curable resin.

Further, the mold release film of the present invention has excellent followability to a mold requiring significant deformation and thus, will follow without being ruptured, to a mold which is deep or, in some cases, complicated in shape, as mentioned above. Therefore, at the time of carrying out sealing of a structure, it is less likely to have such a problem that the mold release film will be ruptured, or the curable resin will leak from such a ruptured portion.

Further, the mold release film of the present invention is excellent in close contact with a component which is desired to be exposed at the surface of the structure. Therefore, it is thereby possible to effectively prevent resin burrs which are, otherwise, likely to be formed at the time of sealing.

### [Processes for Producing Sealed Body]

The process for producing a sealed body of the present invention is a process for producing a sealed body having a resin sealed portion with a thickness of at least 3 mm, formed from a substrate, a semiconductor element, connection terminals and a curable resin, by means of a mold comprising an upper mold and a lower mold, of which at least one has a depth of at least 3 mm, characterized by comprising:

a step of disposing the above described mold release film of the present invention on a surface, to be in contact with the curable resin, of said at least one of the upper mold and the lower mold having a depth of at least 3 mm,

a step of disposing a structure comprising a substrate, a semiconductor element and connection terminals in the mold and filling a pace in the mold with the curable resin, followed by curing to form a resin sealed portion having a thickness of at least 3 mm, and

a step of releasing the resin sealed portion together with the structure from the mold.

For the process for producing a sealed body of the present invention, a known production process may be employed except for disposing the mold release film of the present invention on the surface of the mold to be in contact with the curable resin at the time of producing the sealed body.

For example, as a method of forming the resin sealed portion, a compression molding method or transfer molding method may be mentioned, and as an apparatus to be used in such a case, it is possible to use a known compression-molding apparatus or transfer molding apparatus. The production conditions may also be the same as the conditions in a known method for producing a semiconductor package.

The sealed body to be produced by the process for producing a sealed body of the present invention is not particularly limited, so long as it is one comprising a substrate, a semiconductor element, connection terminals and a resin sealed portion with a thickness of at least 3 mm.

The sealed body may, for example, be a power semiconductor module, a hybrid memory cube, etc. The thickness of the resin sealed portion is preferably from 3 to 10 mm, particularly preferably from 3 to 7 mm.

### First Embodiment

As an embodiment of the process for producing a sealed body, a case for producing a sealed body 110 shown in FIG. 3 by a compression molding method by using the mold release film 1 shown in FIG. 1, will be described. The process for producing a sealed body according to this embodiment, comprises the following steps (α1) to (α5):

(α1) a step of disposing the mold release film 1 on the lower mold of the mold comprising the lower mold having a concave portion with a depth of at least 3 mm and the upper mold not having a concave portion with a depth of at least 3 mm, so that the mold release film 1 covers the concave portion of the lower mold,

(α2) a step of vacuum-suctioning the mold release film 1 to the side of the cavity surface of the lower mold,

(α3) a step of filling the curable resin in the concave portion of the lower mold,

(α4) a step of disposing a structure (hereinafter referred to as the structure 130) comprising a substrate 16, a laminate structure 17 and through-silicon vias 18 between the upper mold and the lower mold, closing the upper mold and the lower mold, and filling the curable resin in a cavity formed between the upper mold and the lower mold, followed by curing to form a resin sealed portion 19 thereby to obtain a sealed body 110, and

(α5) a step of taking out the sealed body 110 from the mold.

Sealed Body:

FIG. 2 is a schematic cross-sectional view of the sealed body 110 to be produced by the process for producing a sealed body according to the first embodiment.

The sealed body 110 is a hybrid memory cube and comprises a substrate 16, a laminate structure 17 having a plurality of semiconductor chips 17a laminated, a plurality of through-silicon vias (connection terminals) 18 and a resin sealed portion 19.

The through-silicon vias 18 pass through the laminate structure and connect the plurality of semiconductor chips 17a. The resin sealed portion 19 is formed on the substrate 16 and seals the semiconductor chips 17a and the through-silicon vias 18. The thickness D1 of the resin sealed portion 19 is at least 3 mm.

Mold:

As the mold in the first embodiment, one known as a mold to be used for a compression molding may be employed. For example, as shown in FIG. 3, a mold comprising a fixed upper mold (upper mold) 20, a cavity bottom member 22 and a frame-shaped movable member 24 disposed at the periphery of the cavity bottom member 22, may be mentioned.

In the fixed upper mold 20, a vacuum vent (not shown) is formed to adsorb the substrate 10 to the fixed upper mold 20 by suctioning air between the substrate 10 and the fixed upper mold 20. Further, in the cavity bottom member 22, a vacuum vent (not shown) is formed to adsorb the mold release film 1 to the cavity bottom member 22 by suctioning air between the mold release film 1 and the cavity bottom member 22.

In this mold, the lower mold is constituted by the cavity bottom member 22 and the movable member 24. By moving the movable member 24 up and down, the depth of the lower mold can be changed. By the upper surface of the cavity bottom member 22 and the inner side surface of the movable member 24, the concave portion 26 is formed in a shape corresponding to the shape of the resin sealed portion 19 to be formed in step (α4).

Hereinafter, the upper surface of the cavity bottom member 22 and the inner side surface of the movable member 24, may be collectively referred to also as a cavity surface.

Step (α1):

On the movable member 24, the mold release film 30 is disposed to cover the upper surface of the cavity bottom member 22. At that time, the mold release film 1 is disposed so that the surface 2a on the side of the first layer 2 faces upwards (opposite direction to the direction of the cavity bottom member 22).

Typically, the mold release film 1 is sent out from an unwind roll (not shown) and wound up by a wind-up roll (not shown). The mold release film is pulled by the unwind roll and the wind-up roll, and therefore is disposed on the movable member 24 in a stretched state.

Step (α2):

Separately, by vacuum suctioning through a vacuum vent (not shown) of the cavity bottom member 22, the space between the upper surface of the cavity bottom member 22 and the mold release film 1 is evacuated, so that the mold release film 1 is stretched, deformed and vacuum-adsorbed on the upper surface of the cavity bottom member 22. Further, by tightening the frame-shaped movable lower mold 24 disposed at the periphery of the cavity bottom member 22, the mold release film 1 is pulled from all directions to be in tension.

Here, the mold release film 1 may not necessarily be in close contact with the cavity surface, depending upon the strength and thickness of the mold release film 1 in a high temperature environment, and the shape of the concave portion formed by the upper surface of the cavity bottom member 22 and the inner side surfaces of the movable lower mold 24. At the stage of vacuum suctioning in step (α2), as shown in FIG. 3, a void space may be slightly left between the mold release film 1 and the cavity surface.

Step (α3):

As shown in FIG. 3, a curable resin 40 is loaded in a suitable amount onto the mold release film 30 in the concave portion 26 by an applicator (not shown).

Further, separately, by vacuum suctioning through a vacuum vent (not shown) of the fixed upper mold 20, a substrate 10 with the structure 130 is vacuum-adsorbed on the lower surface of the fixed upper mold 20.

As the curable resin 40, various curable resins to be used in the production of semiconductor modules, etc. may be used. A thermosetting resin such as an epoxy resin or a silicone resin is preferred, and an epoxy resin is particularly preferred.

As an epoxy resin, for example, SUMIKON EME G770H type F ver. GR manufactured by Sumitomo Bakelite Co., Ltd., and T693/R4719-SP10 manufactured by Nagase ChemteX Corporation, may be mentioned.

As commercial products of a silicone resin, LPS-3412AJ and LPS-3412B manufactured by Shin-Etsu Chemical Co., Ltd., may, for example, be mentioned.

The curable resin 40 may contain carbon black, fused silica, crystalline silica, alumina, silicon nitride, aluminum nitride, etc.

Here, a case of filling solid one as the curing resin 40 has been described, but the invention is not limited to this, and a curable liquid resin may be filled.

Step (α4):

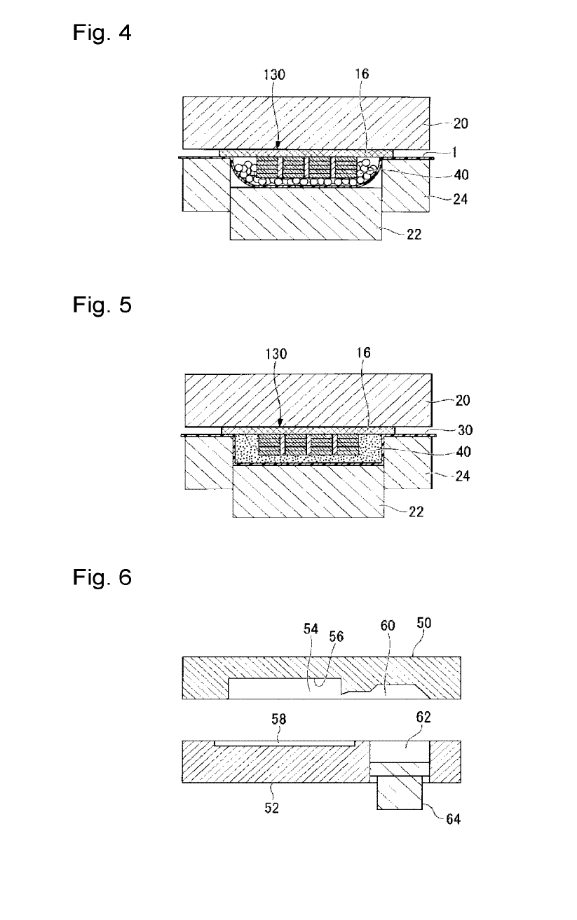

As shown in FIG. 4, in such a state that the curable resin 40 is filled on the mold release film 1 in the concave portion 26, the cavity bottom member 22 and the movable lower mold 24 are raised and clamped to the fixed upper mold 20 for mold clamping.

Then, as shown in FIG. 5, only the cavity bottom member 22 is raised and at the same time, the mold is heated to let the curable resin 40 be cured to form a resin sealed portion 19 for sealing the structure 130, whereby the sealed body 110 is formed.

In the step (α4), by the pressure at the time of raising the cavity bottom member 22, the curable resin 40 filled in the cavity is further pushed to the cavity surface. The mold release film 1 is thereby stretched and deformed to be closely in contact with the cavity surface. Therefore, the resin sealed portion 19 having a shape corresponding to the shape of the concave portion 26 will be formed. The thickness of the resin sealed portion 19 is the same as the height (the depth of the lower mold) from the upper surface of the cavity bottom member 22 to the upper end of the movable member 24 after raising the cavity bottom member 22.

The heating temperature of the mold, i.e. the heating temperature of the curable resin 40 is preferably from 100 to 185° C., particularly preferably from 150 to 180° C. When the heating temperature is at least the lower limit value in the above range, the productivity of the semiconductor package 1 is improved. When the heating temperature is at most the upper limit value in the above range, deterioration of the curable resin 40 is prevented.

From the viewpoint of suppressing a change in the shape of the resin sealed portion 19 due to thermal expansion of the curable resin 40, when the protection of the sealed body 110 is particularly required, the heating is preferably conducted at the lowest possible temperature within the above range.

Step (α5):

The fixed upper mold 20, the cavity bottom member 22 and the movable member 24 are mold-opened, and the sealed body 110 is taken out.

At the same time as releasing the sealed body 110, the used portion of the mold release film 1 is sent to a wind-up roll (not shown), and the unused portion of the mold release film 1 is sent out from an unwind roll (not shown).

The thickness of the mold release film 1 at the time of being transported from the unwind roll to the wind-up roll is preferably at least 43 μm. If the thickness is less than 43 μm, wrinkling is likely to occur during the transportation of the mold release film 1. If wrinkles are formed in the mold release film 1, such wrinkles are likely to be transferred to the resin sealed portion 19, thus leading to a defective product. When the thickness is at least 43 μm, it is possible to apply a sufficient tension to the mold release film 1 so as to prevent formation of wrinkles.

### Second Embodiment

As another embodiment of the process for producing a sealed body, a case of producing a sealed body 110 shown in FIG. 2 by a transfer molding method by using the mold release film 1 shown in FIG. 1, will be described.

The process for producing a semiconductor package in this embodiment comprises the following steps (β1) to (β5):

(β1) a step of disposing the mold release film 1 on the upper mold of the mold comprising the upper mold having a concave portion with a depth of at least 3 mm and the lower mold not having a concave portion with a depth of at least 3 mm, so that the mold release film 1 covers the concave portion of the upper mold,

(β2) a step of vacuum-suctioning the mold release film 1 to the side of the cavity surface of the upper mold,

(β3) a step of disposing a structure 130 comprising a substrate 16, a laminate structure 17 and through-silicon vias 18 at a predetermined position in the lower mold, and closing the upper mold and the lower mold,

(β4) a step of filling the curable resin in a cavity formed between the upper mold and the lower mold, followed by curing to form a resin sealed portion 19 thereby to obtain a sealed body 110, and

(β5) a step of taking out the sealed body 110 from the mold.

Mold:

As the mold in the second embodiment, it is possible to use one known as a mold to be used for a transfer molding method. For example, as shown in FIG. 6, a mold comprising an upper mold 50 and a lower mold 52, may be mentioned. In the upper mold 50, a concave portion 54 having a shape corresponding to the shape of the resin sealed portion 19 to be formed in the step (β4), and a concave-shaped resin-introducing portion 60 to introduce a curable resin 40 to the concave portion 54 are formed. In the lower mold 52, a substrate placement portion 58 for placing a substrate 10 of the structure 130, and a resin placement portion 62 for placing a curable resin 40 are formed. Further, in the resin placement portion 62, a plunger 64 is provided that pushes the curable resin 40 to the resin introducing portion 60 of the upper mold 50.

Step (β1):

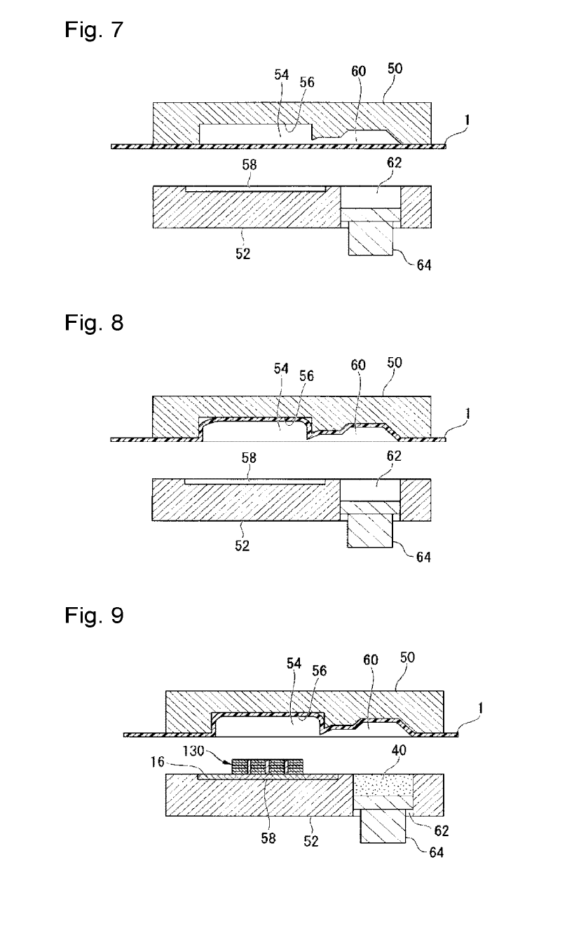

As shown in FIG. 7, the mold release film 1 is disposed to cover the concave portion 54 of the upper mold 50. The mold release film 1 is preferably disposed so as to entirely cover the concave portion 54 and the resin introducing portion 60. Typically, the mold release film 1 is pulled by the unwind roll (not shown) and the wind-up roll (not shown), whereby it is disposed to cover the concave portion 54 of the upper mold 50 in a stretched state.

Step (β2):

As shown in FIG. 8, by vacuum suctioning through a groove (not shown) formed outside of the concave portion 54 of the upper mold 50, the space between the mold release film 1 and the cavity surface 56, and the space between the mold release film 1 and the inner wall of the resin introducing portion 60, are depressurized, so that the mold release film 1 is stretched, deformed and vacuum-adsorbed to the cavity surface 56 of the upper mold 50.

Here, the mold release film 1 may not always be in close contact with the cavity surface 56, depending upon the strength and thickness of the mold release film 1 in a high temperature environment and the shape of the concave portion 54. As shown in FIG. 8, at the stage of the vacuum suctioning in step (β2), a void space may be slightly left between the mold release film 1 and the cavity surface 56.

Step (β3):

As shown in FIG. 9, the substrate 16 of the structure 130 is placed on the substrate placement portion 58, and the upper mold 50 and the lower mold 52 are clamped so that the structure 130 is disposed at a predetermined position in the concave portion 54.

Further, on the plunger 64 of the resin placement portion 62, the curable resin 40 is disposed in advance.

The curable resin 40 may be the same one as the curable resin 40 mentioned in the process (α).

Step (β4):

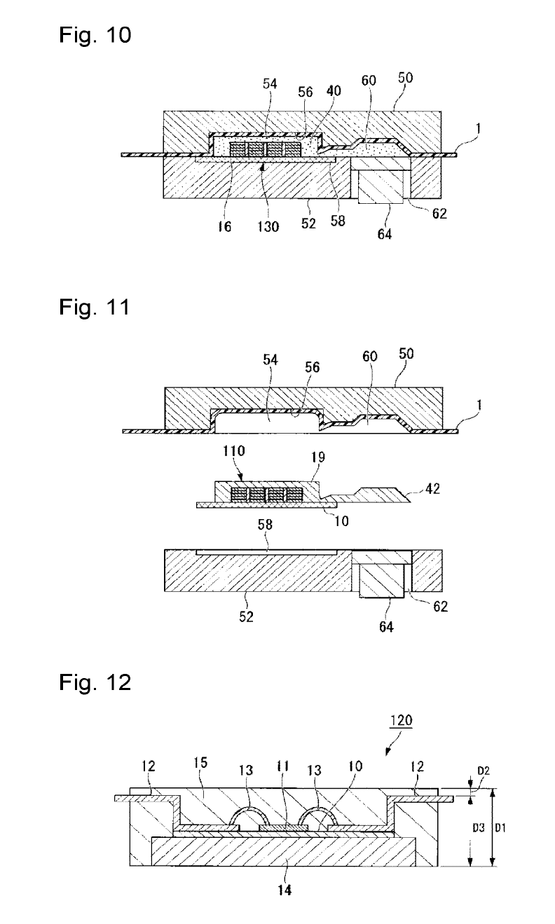

As shown in FIG. 10, the plunger 64 of the lower mold 52 is pushed up to fill the curable resin 40 into the concave portion 54 through the resin introducing portion 60. Then, the mold is heated to cure the curable resin 40, thereby to form the resin sealed portion 19 for sealing the structure 130, whereby the sealed body 110 will be formed. The thickness of the resin sealed portion 19 is the same as the depth of the concave portion 54 of the upper mold 50.

In step (β4), as the curable resin 40 is filled into the concave portion 54, the mold release film 1 is further pushed to the cavity surface 56 side by the resin pressure and stretched and deformed so that it will be in close contact with the cavity surface 56. Therefore, a resin sealed portion 19 having a shape corresponding to the shape of the concave portion 54 will be formed.

The heating temperature of the mold at the time of curing the curable resin 40, namely the heating temperature of the curable resin 40, is preferably within the same range as the temperature range in the process (α).

The resin pressure at the time of filling the curable resin 40 is preferably from 2 to 30 MPa, particularly preferably from 3 to 10 MPa. When the resin pressure is at least the lower limit value in the above range, a drawback such as deficiency in filling the curable resin 40 is unlikely to occur. When the resin pressure is at most the upper limit value in the above range, it is easy to obtain a sealed body 110 of excellent quality. The resin pressure of the curable resin 40, can be adjusted by the plunger 64.

Step (β5):

As shown in FIG. 11, the sealed body 110 is taken out from the mold. At that time, the cured product 42 of the curable resin 40 cured in the resin introducing portion 60 is taken out from the mold together with the sealed body 110 in such a state as attached to the resin sealed portion 19 of the sealed body 110. Therefore, by cutting away the cured product 42 attached to the sealed body 110 taken out, the sealed body 110 is obtained.

In the foregoing, the processes for producing a package for mounting a semiconductor element of the present invention have been described with reference to the first and second embodiments, but the present invention is not limited to the above embodiments. The respective constructions, their combinations, etc. in the above embodiments are exemplary, and additions, omissions, substitutions and other changes are possible within a range not departing from the concept of the present invention.

For example, the timing for peeling the sealed body 110 from the mold release film 1 is not limited at the time of taking out the sealed body 110 from the mold, and the sealed body 110 may be taken out together with the mold release film 1 from the mold, and thereafter, the mold release film 1 may be peeled from the sealed body 110.

In step (α4) or step (β3), instead of the structure 130, a structure wherein a plurality of structures each made of a laminated structure 17 and through-silicon vias 18, are formed on a substrate, is disposed, and after step (α5) or step (β5), the substrate and the resin sealed portion 14 of the sealed body taken out from the mold, are cut (singulated) so that the plurality of structures are individually separated, to obtain singulated sealed bodies.

Such singulation can be carried out by a known method, such as a dicing method. The dicing method is a method of cutting an object by rotating a dicing blade. As the dicing blade, typically a rotating blade (diamond cutter) having diamond powder sintered on the outer periphery of a disk, is used. Singulation by the dicing method can be carried out, for example, by a method wherein the object to be cut (the sealed body), is fixed on the processing table via a jig, and the dicing blade is permitted to run in such a state that a space to insert the dicing blade is present between the jig and the cutting area of the object to be cut.

In the case of conducting the singulation, after the step (cutting step) of cutting the object to be cut, there may be included a foreign matter-removing step of moving the processing table while supplying a liquid to the cutting object from a nozzle disposed at a position apart from the case for covering the dicing blade.

After step (α5) or step (β5), in order to display an optional information, a step of forming an ink layer may be conducted by applying an ink on the surface of the resin sealed portion.

The information to be displayed by the ink layer is not particularly limited, and a serial number, information about the manufacturers, a type of components, etc., may be mentioned. The method for applying the ink is not particularly limited, and for example, various printing methods may be mentioned, such as ink jet printing, screen printing, transfer from a rubber plate, etc. The ink is not particularly limited and may be suitably selected from known inks.

As a method for forming the ink layer, in view of a high curing speed, less bleeding on the package, and little positional displacement of the package as no hot air is applied, a method of using a photocurable ink is preferred, wherein the ink is applied by an ink-jet method on the surface of the resin sealed portion and cured by irradiation with light.

As the photocurable ink, typically, one containing a polymerizable compound (monomer, oligomer, etc.) may be used. To the ink, as the case requires, a coloring material such as a pigment or a dye, a liquid medium (solvent or dispersant), a polymerization inhibitor, a photopolymerization initiator, other various additives, etc. may be added. Other additives include a slip agent, a polymerization accelerator, a penetration enhancer, a wetting agent (humectant), a fixing agent, a fungicide, a preservative, an antioxidant, a radiation absorber, a chelating agent, a pH adjusting agent, a thickeners, etc.

As the light to cure the photocurable ink, ultraviolet ray, visible ray, infrared ray, electron beam or radiation may, for example, be mentioned. As the light source for ultraviolet ray, a germicidal lamp, an ultraviolet fluorescent lamp, a carbon arc, a xenon lamp, a high-pressure mercury lamp for copying, a medium-pressure or high-pressure mercury lamp, a super high pressure mercury lamp, an electrodeless lamp, a metal halide lamp, an ultraviolet light emitting diode, an ultraviolet laser diode, or natural light, may, for example, be mentioned.

Light irradiation may be carried out under normal pressure or under reduced pressure. It may be carried out in air, or in an inert gas atmosphere such as a nitrogen atmosphere or carbon dioxide atmosphere.

The sealed body to be produced by the process for producing a sealed body of the present invention is not limited to the sealed body 110.

FIG. 12 shows a schematic cross-sectional view of another example of the sealed body to be produced by the process for producing a sealed body of the present invention. The sealed body 120 of this example is a power semiconductor module and comprises a substrate 10, a semiconductor chip (semiconductor element) 11, a plurality of connection terminals 12, a plurality of wires 13, a heatsink 14 and a resin sealed portion 15.

Each of the plurality of connection terminals 12 has one end disposed in the vicinity of the semiconductor chip 11 on the substrate 10, extends from that position towards the edge of the substrate 10, is bent at the edge of the substrate 10 in a direction opposite to the substrate 10 side, is further bent in a direction departing from the substrate 10 and protrudes to outside of the resin sealed portion 15. The plurality of wires 13 connect one end of the respective plurality of connection terminals and the semiconductor chip 11. The heatsink 14 is disposed on the lower side of the substrate 10, and the upper surface of the heatsink 14 is in contact with the substrate 10. The resin sealed portion 15 seals portions other than a part of the connection terminals 12 and the bottom surface of the heatsink 14, and the bottom surface of the heatsink 14 is exposed.

The sealed body 120 can be produced in the same manner as in the first and second embodiments except that instead of the structure 130, a structure comprising the substrate 10, the semiconductor chip 11, the connection terminals 12, the wires 13 and the heatsink 14, is used, and a mold having a cavity corresponding to the resin sealed portion 15 is used.

For example, as the upper mold, one having a concave portion in a shape corresponding to the upper side of the resin sealed portion 15 than the position where the connection terminals 12 protrude, is used, and as the lower mold, one having a concave portion in a shape corresponding to the lower side of the resin sealed portion 15 than the position where the connection terminals 12 protrude, is used. When these upper mold and lower mold are clamped, a cavity corresponding to the resin sealed portion 15 is formed.

The sum of the depth D2 of the concave portion of the upper mold and the depth D3 of the concave portion of the lower mold becomes the thickness D1 of the resin sealed portion 15. In this example, D2 shall be less than 3 mm, and D3 shall be at least 3 mm.

In the production of the sealed body 120, the mold release film of the present invention is disposed on the cavity surface of the lower mold, then the above structure is disposed thereon so that the heatsink 14 side faces the lower mold side, and mold clamping is conducted in such a state that the portions of the connection terminals 12 to be not sealed, are sandwiched between the upper mold and the lower mold, followed by transfer molding in the same manner as described above, whereby the sealed body 120 will be formed. At that time, a known mold release film may be disposed on the cavity surface of the upper mold.

The shape of the resin sealed portion is not limited to ones shown in FIG. 2 and FIG. 12. For example, the upper surface or the side surface of the resin sealed portion may not be flat and may have a difference in level.

At the time of forming the resin sealed portion, the semiconductor chip or other components may be directly in contact with the mold release film. In such a case, the portion which is directly in contact with the mold release film, will be exposed from the resin sealed portion.

### EXAMPLES

Hereinafter, the present invention will be described in detail with reference to Examples. However, the present invention is not limited by the following description. Among the following Ex. 1 to 15, Ex. 1 to 10 are Examples of the present invention, and Ex. 11 to 15 are Comparative Examples. The materials and measuring/evaluation methods used in Examples are shown below.

### [Materials Used]

### <Thermoplastic Resin Films>

ETFE film: ETFE (1) obtained in the after-described Production Example 1 was melt-extruded at 320° C. by an extruder provided with a T die having a lip opening degree adjusted, by adjusting the base die roll, the film-forming speed and the nip pressure, to obtain an ETFE film having a thickness of 12 μm, 25 μm, 100 μm or 200 μm.

Polymethylpentenefilm: Polymethylpentene “TPX MX004” (manufactured by Mitsui Chemicals, Inc.) was melt-extruded at 280° C. by an extruder provided with a T die having a lip opening degree adjusted, by adjusting the base die roll, the film-forming speed and the nip pressure, to obtain a polymethylpentene film having a thickness of 25 μm.

PBT film (1): “NOVADURAN 5020” (manufactured by Mitsubishi Engineering-Plastics Corporation, Mw: 70,000, units derived from butanediol/units derived from terephthalic acid=53/47 (molar ratio)) was melt-extruded at 280° C. by an extruder provided with a T die having a lip opening degree adjusted, by adjusting the base die roll, the film-forming speed and the nip pressure, to obtain a PBT film having a thickness of 38, 50, 100 or 150 μm. Here, Tg was 63° C.

PBT film (2): “NOVADURAN 5505S” (manufactured by Mitsubishi Engineering-Plastics Corporation, Mw: 60,000, units derived from butanediol/units derived from terephthalic acid=53/47 (molar ratio), copolymer containing 5 mol % of units derived from polyethylene glycol in all units) was melt-extruded at 280° C. by an extruder provided with a T die having a lip opening degree adjusted, by adjusting the base die roll, the film-forming speed and the nip pressure, to obtain a PBT film having a thickness of 50 μm. Here, Tg was 62° C.

PBT film (3): “NOVADURAN 5026” (manufactured by Mitsubishi Engineering-Plastics Corporation, Mw: 110,000, units derived from butanediol/units derived from terephthalic acid=53/47 (molar ratio)) was melt-extruded at 280° C. by an extruder provided with a T die having a lip opening degree adjusted, by adjusting the base die roll, the film-forming speed and the nip pressure, to obtain a PBT film having a thickness of 100 μm. Here, Tg was 63° C.

PBT film (4): “NOVADURAN 5510S” (manufactured by Mitsubishi Engineering-Plastics Corporation, Mw: 60,000, units derived from butanediol/units derived from terephthalic acid=53/47 (molar ratio), copolymer containing 11 mol % of units derived from polyethylene glycol in all units) was melt-extruded at 280° C. by an extruder provided with a T die having a lip opening degree adjusted, by adjusting the base die roll, the film-forming speed and the nip pressure, to obtain a PBT film having a thickness of 50 μm. Here, Tg was 60° C.

Non-stretched nylon film: DIAMIRON C-Z 50 μm (manufactured by Mitsubishi Plastics, Inc.), Tg: 47° C.

Highly formable PET film: TEFLEX FT 50 μm (manufactured by Teijin DuPont Films Japan Limited), Tg: 101° C.

PET film: Teijin Tetoron G2 50 μm (manufactured by Teijin DuPont Films Japan Limited), Tg: 118° C.

Tg of a film to be used in an Example is a temperature at which tan δ (E″/E′) being a ratio of the loss elastic modulus E″ to the storage elastic modulus E′ as measured in accordance with ISO6721-4: 1994 (JIS K7244-4: 1999) takes the maximum value. Tg was measured by raising the temperature at 2° C./min. from 20° C. to 180° C. at a frequency of 10 Hz, with a static force of 0.98 N and with a dynamic displacement of 0.035%.

Of each film, a surface with Ra being small was used as a bonding surface in dry lamination. Further, in a case where the wet tension of the bonding surface in dry lamination of each film, based on ISO8296: 1987 (JIS K6768: 1999) was lower than 40 mN/m, the surface was subjected to corona treatment to bring the wet tension to be at least 40 mN/m.

### Production Example 1

### Production of ETFE (1)

A polymerization tank having an internal capacity of 1.3 L and equipped with a stirrer, was deaerated; 881.9 g of 1-hydrotridecafluoro-hexane, 335.5 g of 1,3-dichloro-1,1,2,2,3-pentafluoropropane (trade name “AK225cb” manufactured by Asahi Glass Company, Limited, hereinafter referred to as AK225cb) and 7.0 g of CH₂═CHCF₂CF₂CF₂CF₃ (PFBE), were charged; 165.2 g of TFE and 9.8 g of ethylene (hereinafter referred to as E) were injected; the temperature in the polymerization tank was raised to 66° C.; and as a polymerization initiator solution, 7.7 mL of an AK225cb solution containing 1 mass % of tert-butyl peroxypivalate (hereinafter referred to as PBPV) was charged to initiate the polymerization.

A monomer mixture gas of TFE/E=54/46 by molar ratio was continuously charged so that the pressure would be constant during the polymerization. Further, along with the charging of the monomer mixture gas, PFBE was continuously charged in an amount corresponding 1.4 mol % to the total number of moles of TFE and E. After 2.9 hours from the initiation of the polymerization, at the time when 100 g of the monomer mixture gas was charged, the inside temperature of the polymerization tank was lowered to room temperature, and at the same time, the pressure of the polymerization tank was purged to normal pressure.

Thereafter, the slurry was suction filtered through a glass filter, and a solid content was recovered and dried at 150° C. for 15 hours to obtain 105 g of ETFE (1).

ETFE (1) was a copolymer of tetrafluoroethylene/ethylene/PFBE=52.5/46.3/1.2 (molar ratio) and its MFR was 12 g/10 min.

### <Adhesive Layer>

As an adhesive to be used in a dry lamination step for bonding respective films, the following urethane type adhesive A was used.

[Urethane Type Adhesive A]

Main agent: CRISVON NT-258 (manufactured by DIC Corporation)

Curing agent: Coronate 2096 (manufactured by Nippon Polyurethane Industry Co., Ltd.

The main agent and the curing agent were mixed so that the mass ratio in solid content (main agent:curing agent) would be 10:1, and ethyl acetate was used as a diluent.

### [Measuring/Evaluation Methods]

### <Thickness>

The thickness of a film used as the first layer or the second layer in each of Ex. 1 to 8 and Ex. 12 to 13 (or a film used as a mold release film in each of Ex. 9 to 11) was measured by the following procedure.

By means of a contact type thickness meter DG-525H (manufactured by Ono Sokki Co., Ltd.) using probe AA-026 (φ10 mm SR7), the thickness of a film was measured at 10 points so that the distance in the traverse direction would be equal, and the average value was taken as the thickness.

### <Tensile Stress at Break at 180° C.>

The tensile stress at break (unit: MPa) of a film used as the second layer in each of Ex. 1 to 8 and Ex. 12 to 13 (or a film used as a mold release film in Ex. 11) was measured in accordance with ASTM D638. Specifically, the film was punched out in a test specimen type V to prepare a test film, and with respect to the test film, the tensile test was conducted under the conditions of a temperature of 180° C. and a tensile speed of 50 mm/min. to measure the tensile stress at break.

### <Tensile Storage Modulus at 180° C.>

The tensile storage modulus (unit: MPa) of a film used as the second layer in each of Ex. 1 to 8 and Ex. 12 to 13 (or a film used as a mold release film in Ex. 11) was measured by the following procedure.

By means of a dynamic viscoelasticity measuring apparatus SOLID L-1 (manufactured by Toyo Seiki Co., Ltd.), the storage elastic modulus E′ was measured based on ISO6721-4: 1944 (JIS K7244-4: 1999). The size of the sample measured was 8 mm in width×20 mm in length, and E′ measured at 180° C. by raising the temperature at 2° C./min. from 20° C. to 180° C. at a frequency of 10 Hz, with a static force of 0.98 N and with a dynamic displacement of 0.035%, was taken as the tensile storage modulus at 180° C.

### <180° C. Followability Test>

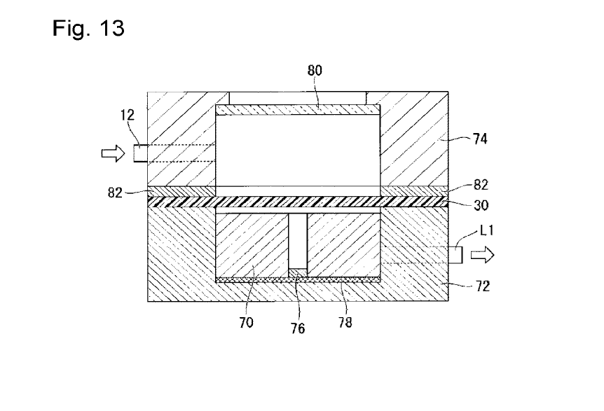

This test method will be described with reference to FIG. 13.

As shown in FIG. 13, the apparatus used for this test comprises a doughnut-form frame 70 (made of stainless steel, thickness: 9 mm) having a cylindrical hole with a diameter of 10 mm at its center, a lower mold 72, an upper mold 74 and a top 76.

In the lower mold 72, a concave portion capable of accommodating the frame 70 is formed. At the bottom surface of the concave portion, a stainless steel mesh 8 is disposed. To the lower mold 72, a piping L1 is connected, and to the piping L1, a vacuum pump (not shown) is connected, so that air in the concave portion can be depressurized.

At the center of the upper mold 74, a hole is provided, and the upper side (opposite side to the lower mold 72 side) opening is closed by a glass roof window 80. To the upper mold 74, a piping L2 is connected, so that compressed air can be supplied via the piping L2 into the hole of the upper mold 74.

In the test, firstly the frame 70 is placed on the mesh 78, the top 76 is placed in the hole of the frame, and the lower mold 72 and the upper mold 74 are clamped by a screw (not shown) in such a state that a packing 82 and the mold release film 30 as an object to be evaluated, are sandwiched. Thus, the mold release film 30 is fixed. Further, air tight spaces are formed, respectively, between the mold release film 30 and the cavity surface of the lower mold 72 and between the mold release film 30, and the roof window 76 and the inner peripheral surface of the hole of the upper mold 74.

At that time, there are slight spaces between the side surface of the concave portion of the lower mold and the outer peripheral surface of the frame 70 and between the mold release film 30 and the top surface of the frame 70. Further, by the presence of the mesh 78, the bottom surface of the concave portion of the lower mold 72 and the frame 70 are made not to be closely in contact with each other.

Thus, after fixing the mold release film 30, by depressurizing inside of the concave portion of the lower mold 72 via the piping L1 and, as the case requires, by supplying compressed air into the hole of the upper mold 74 via the piping L2, it is possible to suction the mold release film 30 to the frame 70 side and to stretch it so that it will be in close contact with the inner peripheral surface of the hole of the frame 70 and with the upper surface of the top 76.

Further, by changing the thickness of the top 76 to be put in the hole of the frame 70, it is possible to change the following-up depth i.e. the distance between the upper surface of the frame 70 and the upper surface of the top 76.

In the test, firstly, by using, as the top 76, one having a following-up depth of 3 mm or 7 mm, the mold release film 30 was fixed by the above-mentioned procedure. At that time, in a case where the mold release film 30 was a laminate film having a second layer and a first layer laminated, it was disposed so that the surface of the second layer side faced the frame 70 side. Then, the entire apparatus was heated to 180° C. by a hot plate (not shown) disposed under the lower mold 72, and then, the vacuum pump was operated to withdraw air between the top 76 and the mold release film 30. Further, compressed air (0.5 MPa) was supplied from the piping L2 into the spaces to let the mold release film 30 follow the frame 70 and the top 76. That state was maintained for 3 minutes, and the presence or absence of pinholes was ascertained by the degree of vacuum. Specifically, a case where the degree of vacuum was at least −90 kPa, was regarded that pinholes were present. The results were evaluated by the following standards.

∘ (Good): No pinholes were present.

x (No good): Pinholes were present.

Further, the film was observed from the roof window 80, and whether or not the mold release film 30 was in contact with the corner in the hole of the frame 70 (the portion where the upper surface of the top 76 and the inner peripheral surface of the hole of the frame 70 intersect), was visually ascertained, whereby the followability to the mold was evaluated by the following standards.

∘ (Good): It was in contact.

x (No good): It was not in contact.

### <Epoxy Resin Releasability>

On a metal plate with a square shape of 15 cm×15 cm (thickness: 3 mm), a polyimide film with a square shape of 15 cm×15 cm (trade name: UPILEX 125S, manufactured by Ube Industries, Ltd., thickness: 125 μm) was placed. Further, on the polyimide film, as a spacer, a polyimide film (thickness: 3 mm) with a square shape of 15 cm×15 cm and having a rectangular hole of 10 cm×8 cm formed at its center, was placed. In the vicinity of the center of the hole, 2 g of an epoxy granular resin for sealing a semiconductor (trade name: SUMIKON EME G770H type F ver. GR, manufactured by Sumitomo Bakelite Co., Ltd.) was placed. Further, thereon, the mold release film with a square shape of 15 cm×15 cm was placed so that the first surface faces the lower side (the epoxy resin side), and finally, thereon, a metal plate (thickness: 3 mm) with a square shape of 15 cm×15 cm was placed, to obtain a laminate sample.

The laminate sample was put into a press machine (50 t press machine, pressing area: 45 cm×50 cm) heated to 180° C. and pressed for 5 minutes under a pressure of 100 kg/cm², to let the epoxy resin be cured. The laminate sample was taken out, and the metal plate and the polyimide films were removed, and the temperature was returned to room temperature. The behavior of the mold release film at that time was visually ascertained, and the behavior at the time of peeling the mold release film by a hand, was ascertained, whereupon the epoxy resin releasability was evaluated by the following standards.

∘ (Good): Spontaneously peeled when cooled. Can be easily peeled by a hand.

x (No good): Not spontaneously peeled when cooled. Cannot be easily peeled by a hand.

### Ex. 1

On one side of the 100 μm PBT film (1), the urethane type adhesive A was applied in an amount of 0.5 g/m² by gravure coating, and a corona treated surface of a 25 μm ETFE film was bonded by dry lamination to obtain a mold release film. The dry lamination conditions were set to be a substrate width of 1,000 mm, a transporting speed of 20 m/min., a drying temperature of from 80 to 100° C., a laminate roll temperature of 25° C., and a roll pressure of 3.5 MPa.

### Ex. 2 to 10, and Ex. 14 to 15

A mold release film was obtained in the same manner as in Ex. 1 by selecting the first layer and the second layer as described in Tables 1 and 2.

### Ex. 11 to 13

The film corresponding to the first layer or the second layer as described in Tables 1 and 2 was used as it is, as a mold release film.

The film construction of the mold release film, the tensile stress at break (MPa) of the second layer, the tensile storage modulus (MPa) at 180° C. of the second layer, the product of the thickness (μm) and the tensile stress at break (MPa) of the second layer (180° C. tensile stress at break×thickness), the product of the thickness (μm) and the tensile storage modulus (MPa) of the second layer (180° C. tensile storage modulus×thickness), and the evaluation results (epoxy resin releasability, 180° C. followability test) in Ex. 1 to 15, are shown in Tables 1 and 2.

In the film construction, the types, thicknesses (μm) and Ra of both surfaces, of the films corresponding to the first layer and the second layer, are shown. Ra values of each of the first and second layers in Tables 1 and 2 are shown in the upper and lower two lines, and the smaller one between the two is of a dry-laminated surface, and the larger one between the two is of a surface not dry-laminated.

TABLE 1

| Ex. | | | 1 | 2 | 3 | 4 | 5 | 6 | 7 | 8 |
|---|---|---|---|---|---|---|---|---|---|---|
| Film | First film | Film | ETFE | ETFE | ETFE | ETFE | ETFE | ETFE | Polymethyl | ETFE |
| construction | | | film | film | film | film | film | film | pentene | film |
| | | | | | | | | | film | |
| | | Thickness | 25 | 12 | 25 | 12 | 25 | 25 | 25 | 25 |
| | | (μm) | | | | | | | | |
| | | Ra | 0.1 | 0.1 | 0.1 | 0.1 | 0.1 | 0.1 | 0.1 | 0.1 |
| | | | 0.1 | 0.1 | 0.1 | 0.1 | 0.1 | 0.1 | 0.1 | 0.1 |
| | Second | Film | PBT film | PBT film | PBT film | PBT film | Non- | Highly | PBT film | PBT film |
| | film | | (1) | (1) | (1) | (1) | stretched | formable | (1) | (2) |
| | | | | | | | nylon film | PET film | | |
| | | Thickness | 100 | 100 | 50 | 38 | 50 | 50 | 100 | 50 |
| | | (μm) | | | | | | | | |
| | | Ra | 0.1 | 0.1 | 0.1 | 0.1 | 0.1 | 0.1 | 0.1 | 0.1 |
| | | | 1.8 | 1.8 | 1.2 | 0.8 | 0.1 | 0.2 | 1.8 | 1.2 |

| | | | | | | | | |
|---|---|---|---|---|---|---|---|---|
| Thickness of mold release film (μm) | 125 | 112 | 75 | 50 | 75 | 75 | 125 | 75 |
| 180° C. tensile stress at break of | 60 | 60 | 60 | 60 | 85 | 65 | 60 | 40 |
| second layer (MPa) | | | | | | | | |
| 180° C. tensile storage modulus of | 120 | 120 | 120 | 120 | 280 | 70 | 120 | 160 |
| second layer (MPa) | | | | | | | | |
| 180° C. tensile stress at break × | 6,000 | 6,000 | 3,000 | 2,280 | 4,250 | 3,250 | 6,000 | 2,000 |
| thickness of the second layer | | | | | | | | |
| (MPa · μm) | | | | | | | | |
| 180° C. tensile storage modulus × | 12,000 | 12,000 | 6,000 | 4,560 | 14,000 | 3,500 | 12,000 | 8,000 |
| thickness of the second layer | | | | | | | | |
| (MPa · μm) | | | | | | | | |
| Epoxy resin releasability | ∘ | ∘ | ∘ | ∘ | ∘ | ∘ | ∘ | ∘ |
| 180° C. followability test 3 mm | ∘/∘ | ∘/∘ | ∘/∘ | ∘/∘ | ∘/∘ | ∘/∘ | ∘/∘ | ∘/∘ |
| (pinholes/followability) | | | | | | | | |
| 180° C. followability test 7 mm | ∘/∘ | ∘/∘ | ∘/∘ | ∘/∘ | ∘/∘ | ∘/∘ | ∘/∘ | x/— |
| (pinholes/followability) | | | | | | | | |
| [180° C. tensile storage modulus × | 2 | 2 | 2 | 2 | 3.3 | 1.1 | 2 | 4 |
| thickness of the second layer | | | | | | | | |
| (MPa · μm)]/[180° C. tensile stress at | | | | | | | | |
| break × thickness of the second layer | | | | | | | | |
| (MPa · μm)] | | | | | | | | |

TABLE 2

| Ex. | | | 9 | 10 | 11 | 12 | 13 | 14 | 15 |
|---|---|---|---|---|---|---|---|---|---|
| Film | First film | Film | ETFE | ETFE | ETFE | ETFE | — | ETFE | ETFE |
| construction | | | film | film | film | film | | film | film |
| | | Thickness | 12 | 12 | 100 | 200 | — | 25 | 25 |
| | | (μm) | | | | | | | |
| | | Ra | 0.1 | 0.1 | 0.1 | 0.1 | — | 0.1 | 0.1 |
| | | | 0.1 | 0.1 | 0.1 | 0.1 | — | 0.1 | 0.1 |
| | Second | Film | PBT film | PBT film | — | — | PBT film | PBT film | PET film |
| | film | | (3) | (4) | | | (1) | (1) | |
| | | Thickness | 100 | 100 | — | — | 100 | 150 | 50 |
| | | (μm) | | | | | | | |
| | | Ra | 0.1 | 0.1 | — | — | 0.1 | 0.1 | 0.1 |
| | | | 1.5 | 1.5 | — | — | 1.8 | 2.0 | 0.2 |

| | | | | | | | |
|---|---|---|---|---|---|---|---|
| Thickness of mold release film (μm) | 112 | 112 | 100 | 200 | 100 | 175 | 75 |
| 180° C. tensile stress at break of | 70 | 25 | — | — | 60 | 60 | 150 |
| second layer (MPa) | | | | | | | |
| 180° C. tensile storage modulus of | 120 | 100 | — | — | 120 | 120 | 500 |
| second layer (MPa) | | | | | | | |
| 180° C. tensile stress at break × | 7,000 | 2,500 | — | — | 6,000 | 9,000 | 7,500 |
| thickness of the second layer | | | | | | | |
| (MPa · μm) | | | | | | | |
| 180° C. tensile storage modulus × | 12,000 | 10,000 | — | — | 12,000 | 18,000 | 25,000 |
| thickness of the second layer | | | | | | | |
| (MPa · μm) | | | | | | | |
| Epoxy resin releasability | ∘ | ∘ | ∘ | ∘ | x | ∘ | ∘ |
| 180° C. followability test 3 mm | ∘/∘ | ∘/∘ | x/— | ∘/x | ∘/∘ | ∘/x | ∘/x |
| (pinholes/followability) | | | | | | | |
| 180° C. followability test 7 mm | ∘/x | x/— | x/— | ∘/x | ∘/∘ | ∘/x | ∘/x |
| (pinholes/followability) | | | | | | | |
| [180° C. tensile storage modulus × | 1.7 | 4 | — | — | 2 | 2 | 3.3 |
| thickness of the second layer | | | | | | | |
| (MPa · μm)]/[180° C. tensile stress at | | | | | | | |
| break × thickness of the second layer | | | | | | | |
| (MPa · μm)] | | | | | | | |

As shown by the above results, the mold release films in Ex. 1 to 10 were confirmed to be excellent in the releasability of the sealed body from the mold, as the evaluation results of the epoxy resin releasability were ∘ (Good).

Further, the mold release films in Ex. 1 to 7 were confirmed to have followability capable of following, without rupturing, to the molds with depths of 3 mm and 7 mm under the temperature conditions at the time of molding, as the evaluation results of the 180° C. followability test were ∘ (Good). The mold release films in Ex. 8 and Ex. 10 had followability capable of following, without rupturing, to a mold with a depth of 3 mm, although pinholes were formed by a mold with a depth of 7 mm. This is considered to be such that in the case of the mold release film in Ex. 8, its value of (180° C. tensile storage modulus×thickness of the second layer)/(180° C. tensile stress at break×thickness of the second layer) was at least 3.8, whereby it was difficult to follow the mold with a depth of 7 mm and by the next compressed air, it rapidly followed the mold, whereby pinholes were formed. Whereas in the case of the mold release film in Ex. 10, it is considered that in PBT forming the second layer, polyalkylene glycol units exceeded 10 mol % in all units, whereby the tensile stress at break was so low that pinholes were formed by the deep mold.

The mold release film in Ex. 9 did not follow the mold with a depth of 7 mm, but to the mold with a depth of 3 mm, it had followability capable of following without rupturing. This is considered to be such that in the mold release film in Ex. 9, in PBT forming the second layer, Mw was more than 100,000, whereby the tensile stress at break was so high that the followability to the deep mold was inadequate.

On the other hand, in the mold release film in Ex. 11 being a single layer film of ETFE with a thickness of 100 μm, rupturing was observed by the mold with a depth of 3 mm in the 180° C. followability test.

In the mold release film in Ex. 12 being a single layer film of ETFE with a thickness of 200 μm, no pinholes were observed, but the followability was not good.

In the mold release film in Ex. 13 being a single layer film of PBT, releasability from the mold was inadequate.

The mold release film in Ex. 14 wherein the thickness of the second layer exceeded 100 μm, did not follow the mold with a depth of at least 3 mm in the 180° C. followability test.

The mold release film in Ex. 15 wherein the value of 180° C. tensile storage modulus×thickness of the second layer exceeded 18,000, did not follow the mold with a depth of at least 3 mm in the 180° C. followability test.

### INDUSTRIAL APPLICABILITY

The mold release film of the present invention and the process for producing a sealed body using it, are widely useful in the production of semiconductor modules of complicated shapes, etc.

This application is a continuation of PCT Application No. PCT/JP2015/056738, filed on Mar. 6, 2015, which is based upon and claims the benefit of priority from Japanese Patent Application No. 2014-045467 filed on Mar. 7, 2014. The contents of those applications are incorporated herein by reference in their entireties.

### REFERENCE SYMBOLS

1: mold release film, 2: first layer, 3: second layer, 10: substrate, 11: semiconductor chip (semiconductor element), 12: connection terminal, 13: wire, 14: heatsink, 15: resin sealed portion, 16: substrate, 17: laminate structure, 17a: semiconductor chip (semiconductor element), 18: through-silicon via (connection terminal), 19: resin sealed portion, 20: fixed upper mold (upper mold), 22: cavity bottom member, 24: movable member, 26: concave portion, 30: mold release film, 40: curable resin, 50: upper mold, 52: lower mold, 54: concave portion, 56: cavity surface, 58: substrate placement portion, 60: resin introducing portion, 62: resin placement portion, 64: plunger, 70: frame, 72: lower mold, 74: upper mold, 76: top, 78: mesh, L1: piping, L2: piping, 80: roof window, 82: packing, 110: sealed body, 120: sealed body, 130: structure

What is claimed is:

1. In a method for producing a sealed body wherein a structure comprising a substrate, a semiconductor element and connection terminals is disposed in a mold comprising an upper mold and a lower mold, of which at least one has a depth of at least 3 mm, and sealed with a curable resin to form a resin sealed portion having a thickness of at least 3 mm, a mold release film to be disposed on a surface, to be in contact with the curable resin, of said at least one of the upper mold and the lower mold having a depth of at least 3 mm, characterized in that
it has a first layer to be in contact with the curable resin at the time of forming the resin sealed portion, and a second layer,
the first layer has a thickness of from 5 to 30 μm and is made of at least one member selected from the group consisting of a fluororesin and a polyolefin having a melting point of at least 200° C., and
the second layer has a thickness of from 38 to 100 μm, a product of the tensile storage modulus (MPa) at 180° C. and the thickness (μm) being at most 18,000 (MPa·μm), and a product of the tensile stress at break (MPa) at 180° C. and the thickness (μm) being at least 2,000 (MPa·μm).

2. The mold release film according to claim 1, wherein the first layer is made of a fluoroolefin type polymer or a polymethylpentene.

3. The mold release film according to claim 1, wherein the first layer is made of a copolymer having units based on a tetrafluoroolefin and units based on ethylene.

4. The mold release film according to claim 1, wherein the second layer is made of a resin for the second layer, and the glass transition temperature of the resin for the second layer is from 40 to 105° C.

5. The mold release film according to claim 1, wherein the second layer is made of at least one member selected from the group consisting of non-stretched polyamide, polybutylene terephthalate and highly formable polyethylene terephthalate.

6. The mold release film according to claim 1, wherein the arithmetic mean roughness (Ra) of the surface on the mold surface side of the second layer is from 1.5 to 2.1 μm.

7. The mold release film according to claim 1, wherein (the tensile storage modulus (MPa) at 180° C.×the thickness (μm))/(the tensile stress at break (MPa) at 180° C.×the thickness (μm)) of the second layer is less than 3.8.

8. A process for producing a sealed body having a resin sealed portion with a thickness of at least 3 mm, formed from a substrate, a semiconductor element, connection terminals and a curable resin, by means of a mold comprising an upper mold and a lower mold, of which at least one has a depth of at least 3 mm, characterized by comprising:
a step of disposing the mold release film as defined in claim 1 on a surface, to be in contact with the curable resin, of said at least one of the upper mold and the lower mold having a depth of at least 3 mm,
a step of disposing a structure comprising a substrate, a semiconductor element and connection terminals in the mold and filling a pace in the mold with the curable resin, followed by curing to form a resin sealed portion having a thickness of at least 3 mm, and
a step of releasing the resin sealed portion together with the structure from the mold.

9. The process for producing a sealed body according to claim 8, which comprises the following steps (α1) to (α5):
(α1) a step of disposing the mold release film on the lower mold of the mold comprising the lower mold having a concave portion with a depth of at least 3 mm and the upper mold not having a concave portion with a depth of at least 3 mm, so that the mold release film covers the concave portion of the lower mold,
(α2) a step of vacuum-suctioning the mold release film to the side of the cavity surface of the lower mold,
(α3) a step of filling the curable resin in the concave portion of the lower mold,
(α4) a step of disposing a structure comprising a substrate, a laminate structure and through-silicon vias between the upper mold and the lower mold, closing the upper mold and the lower mold, and filling the curable resin in a cavity formed between the upper mold and the lower mold, followed by curing to form a resin sealed portion 19 thereby to obtain a sealed body, and
(α5) a step of taking out the sealed body from the mold.

10. The process for producing a sealed body according to claim 8, which comprises the following steps (β1) to (β5):
(β1) a step of disposing the mold release film on the upper mold of the mold comprising the upper mold having a concave portion with a depth of at least 3 mm and the lower mold not having a concave portion with a depth of at least 3 mm, so that the mold release film covers the concave portion of the upper mold,
(β2) a step of vacuum-suctioning the mold release film to the side of the cavity surface of the upper mold,
(β3) a step of disposing a structure comprising a substrate, a laminate structure and through-silicon vias at a predetermined position in the lower mold, and closing the upper mold and the lower mold,
(β4) a step of filling the curable resin in a cavity formed between the upper mold and the lower mold, followed by curing to form a resin sealed portion thereby to obtain a sealed body, and
(β5) a step of taking out the sealed body from the mold.
